(19) United States
(12) Patent Application Publication
(10) Pub. No.: US 2026/0047026 A1
(43) Pub. Date: Feb. 12, 2026

(54) In-Drawer Power Management System

(71) Applicant: Yuyi Lee, La Palma, CA (US)

(72) Inventor: Yuyi Lee, La Palma, CA (US)

(21) Appl. No.: 19/290,394

(22) Filed: Aug. 5, 2025

Related U.S. Application Data
(60) Provisional application No. 63/679,615, filed on Aug. 6, 2024.

(51) Int. Cl. H05K 7/14; H05K 5/02; H05K 7/12; H05K 7/18

(52) U.S. Cl. CPC H05K 7/1457; H05K 5/0247; H05K 7/12; H05K 7/1449; H05K 7/183

(57) ABSTRACT

The in-drawer power management system and methods can include a power outlet charging receptacle dock; a power cord electrically coupled to the power outlet charging receptacle dock; a flexible power cord retainer configured to confine the power cord therethrough; a magnetic mounting plate having an alignment mounting location and a final mounting location, and the magnetic mounting plate configured to align the flexible power cord retainer by magnetic force; and a magnetic mounting bracket configured to align to the alignment mounting location or to the final mounting location through magnetic force.

### PRIORITY BENEFIT TO PROVISIONAL APPLICATION

This utility patent application claims priority benefit to U.S. Provisional Application No. 63/679,615 filed on Aug. 6, 2024.

### TECHNICAL FIELD

The field of the invention is in the power management, power distribution, power supply related products industry.

### BACKGROUND

Charging electrical devices within drawers has proven difficult. The main obstacle to keeping electrical devices powered or charged inside drawers for a cleaner work surface is safely powering and wiring a drawer while providing a quick and easy installation method.

Together with these safety and installation concerns is the ever increasing demand in consumer electronics for less expensive, more functional, more user friendly products. Manufacturing costs and installation costs are necessary aspects of any successful consumer electronics product.

Previous or current available in-drawer apparatuses, systems and methods on the market use rigid or metal in-drawer power cord management, which can introduce the risk of pinching while the drawer is operating, potentially leading to serious injuries. The rigid or metal in-drawer power cord management can also damage the power cord with its sharp edges.

Without proper power cord management and correct installation, placing power outlets and USB chargers inside the drawer can pose safety and electrical hazards, and also impede the drawer's proper function.

There are only a few power cord management solutions available for in-drawer applications on the market. While power cord management solutions offer basic power cord management to prevent kinks when opening and closing the drawer, no complete solution is available that provides power cord management while also being easy and quick to install.

Solutions have been long sought but prior developments have not taught or suggested any complete solutions, and solutions to these problems have long eluded those skilled in the art. Thus there remains a considerable need for devices and methods that are easy to install and can protect against pinching of power cords and prevent fray and shorts caused by traditional sharp and rigid metal power cord management components.

### SUMMARY

An in-drawer power management system and methods, providing easy installation and protection against pinching of power cords and prevent fray and shorts caused by traditional sharp and rigid metal power cord management components, are disclosed. The in-drawer power management system and methods can include: a power outlet charging receptacle dock; a power cord electrically coupled to the power outlet charging receptacle dock; a flexible power cord retainer configured to confine the power cord therethrough; and a magnetic mounting plate configured to align the flexible power cord retainer by magnetic force.

The in-drawer power management system is directed toward a unique, new, non-obvious, and innovative apparatus, system, and method, which solves the problem of providing a power supply management system that keeps electrical devices powered or charged inside drawers for a cleaner work surface is safely powering and wiring a drawer while providing a quick and easy installation method. Without proper power cord management and correct installation, placing power outlets and USB chargers inside the drawer can pose safety and electrical hazards, and also impede the drawer's proper function.

Accordingly, it has been discovered that one or more embodiments of the in-drawer power management system provides an apparatus, and method that provides power charging for electrical devices inside drawers that is easy to install with magnetic mounting components which eliminates the need for precise management, contains a soft and flexible retainer cord system that protects against pinching of power cords and prevents fray and shorts caused by traditional sharp and rigid metal power cord management components.

The in-drawer power management system also further includes objects, features, aspects, and advantages in addition to or in place of those mentioned above. These objects, features, aspects, and advantages of the disclosed invention will become more apparent from the following detailed description of preferred embodiments of the invention, along with the accompanying drawings.

An object of the subject matter of the disclosed invention is to provide an apparatus, system, and method that provides an easy to install in-drawer power management system. Another object of the subject matter of the disclosed invention is to provide an apparatus, system, and method that provides a unique magnetic mounting system and method that enable quick installation with greater mounting tolerance, reducing time and machining costs associated with power cord management installation.

Another object of the subject matter of the disclosed invention is to provide an apparatus, system, and method that provides a soft and flexible retainer cord system which protects against pinching of power cords and prevents fray and shorts caused by traditional sharp and rigid metal power cord management components. The soft & flexible retainer cord system allows the power receptacle ports to be in a fixed position inside the drawer but still be move in unison with the drawer when it is pulled out or pushed back into the housing.

Another object of the subject matter of the disclosed invention is to provide an apparatus, system, and method that allows for manufacturers to produce drawers separately, and then complete final assemblies on a production line for more efficient throughput.

Another object of the subject matter of the disclosed invention is to provide an apparatus, system, and method that provides for an in-drawer power management system that is universal and can be installed and used in a variety of different types of drawers and drawer setups.

Many alterations and modifications may be made by those having ordinary skill in the art without departing from the spirit and scope of the subject matter of the disclosed invention. Therefore, it must be understood that any illustrated or preferred embodiments discussed in this application have been set forth only for the purposes of example, and that it should not be taken as limiting the subject matter of the disclosed invention.

Thus, preferred or illustrative embodiments of the apparatus, system, and method, that provide an in-drawer power management system have been disclosed. It should be apparent, however, to those skilled in the art that many more modifications besides those already described are possible without departing from the in-drawer power management system as disclosed herein. While aspects of the in-drawer power management system have been described with reference to at least one exemplary embodiment, it is to be clearly understood by those skilled in the art that the invention is not limited thereto.

### BRIEF DESCRIPTION OF THE DRAWINGS

The in-drawer power management system is illustrated in the figures of the accompanying drawings which are meant to be exemplary and not limiting, in which like reference numerals are intended to refer to like components, and in which:

FIG. 1 is a drawing illustrating an exploded view of the exemplary embodiment of the in-drawer power management system subject matter of the disclosed invention.

FIG. 2 is a top-down view of the in-drawer power management system subject matter of the disclosed invention.

FIG. 3 is a front view of the in-drawer power management system subject matter of the disclosed invention.

FIG. 4 is a back view of the in-drawer power management system subject matter of the disclosed invention.

FIG. 5 is perspective front view of the in-drawer power management system subject matter of the disclosed invention.

FIG. 6 is an illustration showing an example of how the in-drawer power management system subject matter of the disclosed invention would be seen after being installed inside a drawer.

FIG. 7 is a method of installing the in-drawer power management system.

### DETAILED DESCRIPTION

In the following description, reference is made to the accompanying drawings that form a part hereof, and in which are shown by way of illustration, embodiments in which the invention may be practiced. It is to be understood that other embodiments may be utilized and structural changes may be made without departing from the scope of the inventive subject matter.

The advantages of the in-drawer power management system subject matter of the disclosed invention include, but not limited to, (1) simplicity; (2) lower maintenance; (3) fewer moving parts; (4) fast and easy installation; (5) production efficiency improvements, (6) universal application; (7) prevention and elimination of risk of pinch and power cord damage by traditional rigid-in-drawer power management, (8) magnetic mounting options that includes, but is not limited to, a magnetic mounting bracket which attaches to a magnetic mounting plate, which offers a quick way for plate mounting eliminating the need for precise alignment; (9) ability to install parts separately and put together at a later time to double the benefits.

As used herein, the term “couple” as in “coupling” or “coupled” means a direct or indirect physical connection between coupled elements. When used as “electrically coupled” this means the components are directly or indirectly connected electrically.

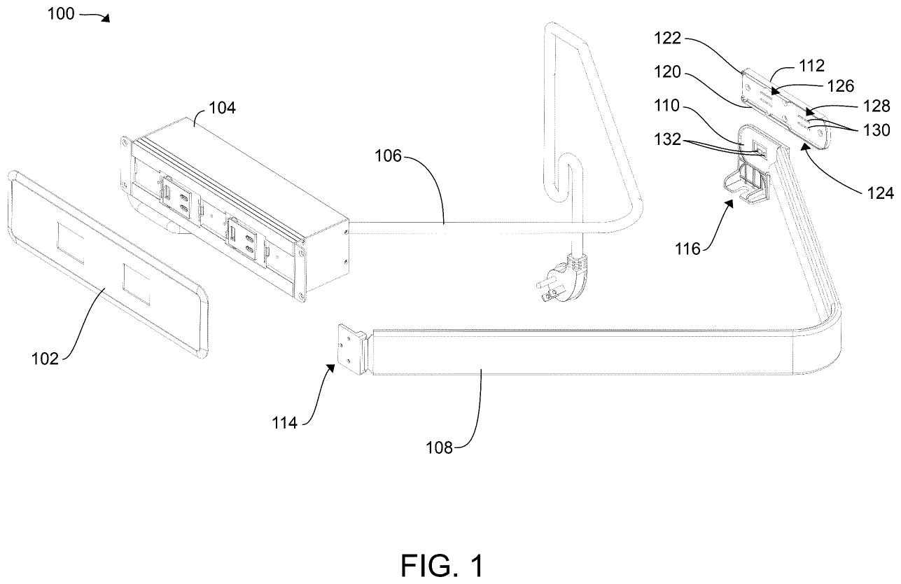

Referring now to FIG. 1, therein is shown an exploded view of an embodiment of an in-drawer power management system 100. In particular, FIG. 1 shows a cover plate 102(1), a power outlet charging receptacle dock 104, a power cord 106; a flexible power cord retainer 108 for said power cord 106; a magnetic mounting bracket 110; and a magnetic mounting plate 112.

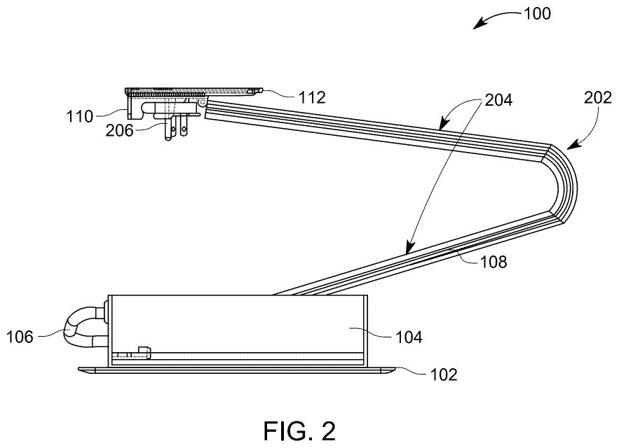

The magnetic mounting plate 112 and the magnetic mounting bracket 110 can be formed of magnetic material for providing a magnetic force. For example the magnetic mounting plate 112 and the magnetic mounting bracket 110 can include magnets, or be magnets themselves. The flexible power cord retainer 108 includes a drawer coupling attachment 114. configured to confine, capture, and guide the power cord 106 therethrough, as depicted in FIG. 2.

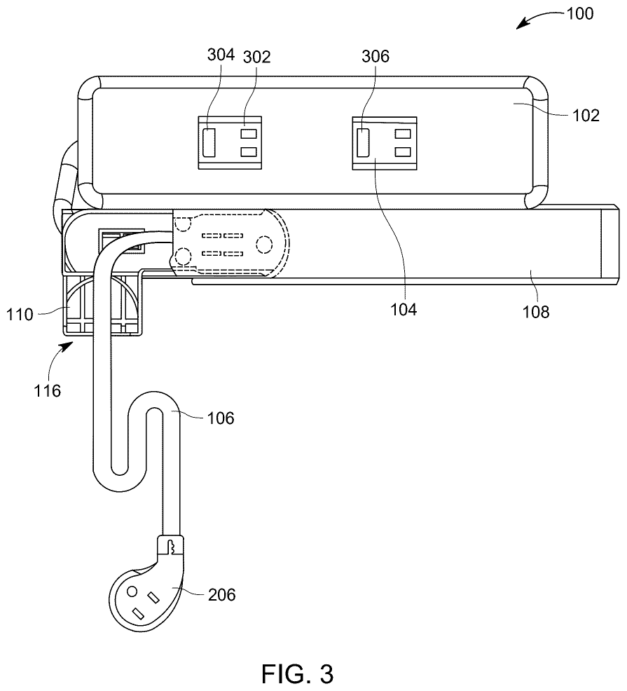

The magnetic mounting bracket 110 includes a bottom groove 116 for directing the power cord 106 therethrough. The magnetic mounting plate 112 can include clips 120, a clip backstop 122, and a clip opening 124. The magnetic mounting bracket 110 can be inserted into the clip opening 124 and slid through the clips 120 to the clip backstop 122 for a secure fit of the magnetic mounting bracket 110 to the magnetic mounting plate 112 as shown in FIGS. 2 and 3, below.

The magnetic mounting plate 112 includes multiple mounting locations for the magnetic mounting bracket 110. Particularly, the magnetic mounting plate 112 includes a final mounting location 126 backed by the clip backstop 122 and an alignment mounting location 128 surrounded by the clip opening 124; each of these mounting locations include plate magnets 130.

The magnetic mounting bracket 110 includes corresponding bracket magnets 132 that will mate with the plate magnets 130 in either the final mounting location 126 or the alignment mounting location 128. The bracket magnets 132 of the magnetic mounting bracket 110 can mate with the plate magnets 130 at the alignment mounting location 128 for initial alignment during product installation, and then the magnetic mounting bracket 110 can be slid through and retained by the clips 120, over to the final mounting location 126 where the plate magnets 130 will again mate with and align the bracket magnets 132.

It is contemplated that the magnetic mounting bracket 110 should be slid from the alignment mounting location 128 to the final mounting location 126 as the final assembled location that the magnetic mounting bracket 110 needs to be in order for the system to operate normally, otherwise, if the magnetic mounting bracket 110 only sits on the alignment mounting location 128, the magnetic mounting bracket 110 may fall during later normal operations.

It has been discovered that the magnetic mounting bracket 110 can be attached to the magnetic mounting plate 112 by blindly aligning the magnetic mounting bracket 110 with the alignment mounting location 128 of the magnetic mounting plate 112 and then, again, blindly slid over to the final mounting location 126 of the magnetic mounting plate 112; this reduces time, cost, and complexity of installation. The bracket magnets 132 of the magnetic mounting bracket 110 and the plate magnets 130 magnetic mounting plate 112 also interact with and align with other magnetic elements such as the straight sections 204 of FIG. 2 of the flexible power cord retainer 108.

The magnetic mounting bracket 110 can be slid along the magnetic mounting plate 112 and be affixed either at the final mounting location 126. Both the magnetic mounting bracket 110 and the magnetic mounting plate 112 can be magnetic, interacting with one another and with the straight sections 204 of the flexible power cord retainer 108.

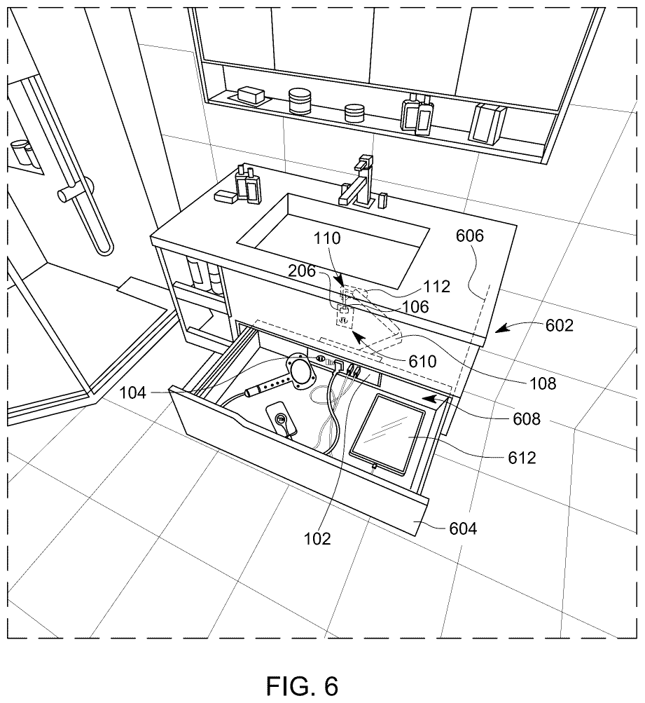

The power outlet charging receptacle dock 104 can be affixed to a front or inner surface of the back drawer wall 608 of FIG. 6 and extend through the back drawer wall 608 while the cover plate 102 covers the attachment point of the power outlet charging receptacle dock 104. The power outlet charging receptacle dock 104 therefore is easy to install in the drawer 604 of FIG. 6. The power outlet charging receptacle dock 104 can include multiple charging ports, USB charging ports, and other configurations.

Referring now to FIG. 2, therein is shown a top-down view of the in-drawer power management system 100 where the cover plate 102 is attached to the power outlet charging receptacle dock 104. The power cord 106 which is covered by the flexible power cord retainer 108, which is coupled to the magnetic mounting bracket 110 that is attached to the magnetic mounting plate 112.

As seen in FIG. 2, a preferred embodiment of the length of the flexible power cord retainer 108 flexible power cord retainer is 24 inches. In this embodiment, the maximum opening allowable for a drawer is 22.45 inches and the minimum is 0 inches allowing the straight sections 204 to collapse together in direct contact and fold below the power outlet charging receptacle dock 104. The magnetic mounting plate 112 can be 4.61 inches wide.

The power cord 106 is shown extending out in a first direction and then down to curve below the power outlet charging receptacle dock 104. The power cord 106 together with the flexible power cord retainer 108 are shown extending below the power outlet charging receptacle dock 104 in a second direction.

The flexible power cord retainer 108 is depicted with a foldable section 202 between two straight sections 204. The power cord 106 is shown with a plug 206 such as a male electrical plug for plugging into the wall outlet 610 of FIG. 6.

Referring now to FIG. 3, therein is shown a front view of the in-drawer power management system 100, where the length of the power cord 106 is illustratively 54 inches without the plug 206, for example, and is shown extending longer than the flexible power cord retainer 108. It is contemplated that in one preferred embodiment, the power outlet charging receptacle dock 104 includes regular three-prong and dual prong power ports 302 and a variety of USB ports such as USB-A 304 and USB-C 306.

The cover plate 102 in one contemplated embodiment can be 10.79 inches by 2.97 inches. The placement of the flexible power cord retainer 108 is shown below the cover plate 102 and below the power outlet charging receptacle dock 104.

The power cord 106 is shown extending through the flexible power cord retainer 108, and down through the bottom groove 116 of the magnetic mounting bracket 110.

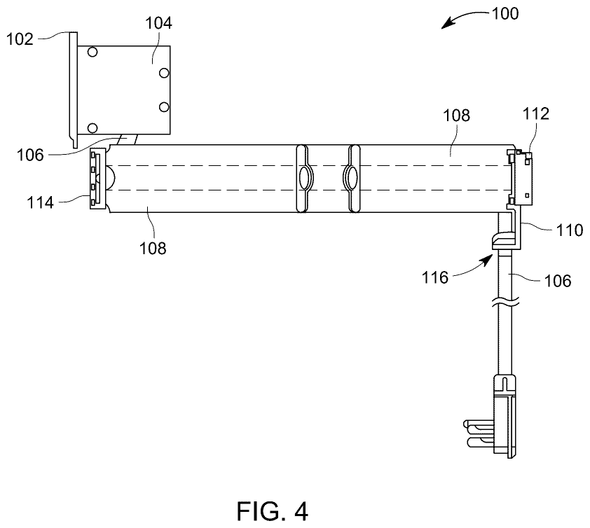

Referring now to FIG. 4, therein is shown a back view of the in-drawer power management system 100 including a preferred and illustrative location of the magnetic mounting bracket 110. The magnetic mounting bracket 110 can be seen having the power cord 106 extending down thorough the bottom groove 116.

At the other end of the power cord 106, the drawer coupling attachment 114 is shown having the power cord 106 extended up to the power outlet charging receptacle dock 104. The power outlet charging receptacle dock 104 is shown being 2.59 inches by 2.22 inches with a total height including the flexible power cord retainer 108 and the cover plate 102 of 4.67 inches.

Once the magnetic mounting plate 112 is secured to an inner surface of the back cabinet wall 606, the power outlet charging receptacle dock 104 and the flexible power cord retainer 108 can be easily aligned by magnetic force and locked into place.

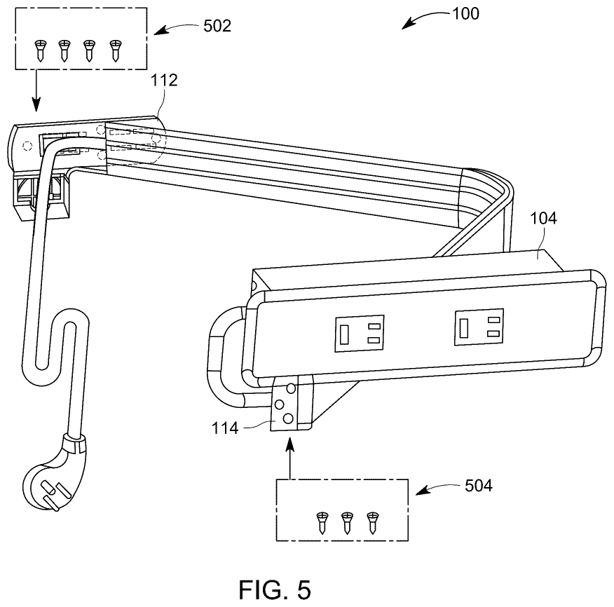

Referring now to FIG. 5, therein is shown a perspective front view of the in-drawer power management system 100 showing a plurality of cabinet mounting screws plurality of screws 502 for anchoring and affixing the magnetic mounting plate 112 to the back cabinet wall 606 of FIG. 6. The cabinet mounting screws 502 can for example be four PA3X15 screws.

The in-drawer power management system 100 further is shown to include drawer mounting screws 504 that can couple and affix the drawer coupling attachment 114 to a back or outer surface of the back drawer wall 608 of FIG. 6. The drawer mounting screws 504 can for example be three KA3X15 screws.

Referring now to FIG. 6, therein is shown an illustrative example showing the installation of the in-drawer power management system 100 in a cabinet 602 with a drawer 604.

The magnetic mounting plate 112 is shown attached to a back cabinet wall 606 of the cabinet 602 and coupled to the magnetic mounting bracket 110 and the power cord 106. The power outlet charging receptacle dock 104 is shown extending through a back drawer wall 608 of the drawer 604.

The cover plate 102 is shown covering the power outlet charging receptacle dock 104 and in direct contact with the back drawer wall 608. The plug 206 at the end of the power cord 106 is shown plugged into a wall outlet 610.

As shown and in most embodiments, the magnetic mounting plate 112 with the magnetic mounting bracket 110 will be mounted to the back cabinet wall 606 above the wall outlet 610 with the power cord 106 extending down to the wall outlet 610.

The magnetic mounting method comprising the magnetic mounting bracket 110 and the magnetic mounting plate 112 together with the flexible power cord retainer 108 of the present disclosure enables quick installation with greater mounting tolerance, reducing time and machining costs associated with power cord management installation. This not only simplifies field installation but also allows manufacturers to produce drawer parts separately, and then complete final assembly on a production line for more efficient throughput. Thus the in-drawer power management system 100 can reduce both manufacturing costs and installation costs.

Once the magnetic mounting plate 112 is secured to the back cabinet wall 606, the power outlet charging receptacle dock 104 and the flexible power cord retainer 108 can be easily aligned by magnetic force and locked into place. The present disclosure of the flexible power cord retainer 108 also prevents fray and shorts caused by traditional sharp and rigid metal power cord management components and keeps electrical devices 612 powered or charged inside drawers.

Contemplated electrical devices 612 can include video-graphic devices, and computer devices such as cell phones and tablet computers. As will be appreciated, the magnetic mounting plate 112 can be mounted to an inner surface of the back cabinet wall 606 facing a back surface of the back drawer wall 608 such that the magnetic mounting plate 112 faces the drawer coupling attachment 114 of FIG. 1 when each of them are mounted within the cabinet 602. Further, the magnetic mounting plate 112 and the magnetic mounting bracket 110 can face the back side of the cover plate 102 and the power outlet charging receptacle dock 104 when mounted to the cabinet 602.

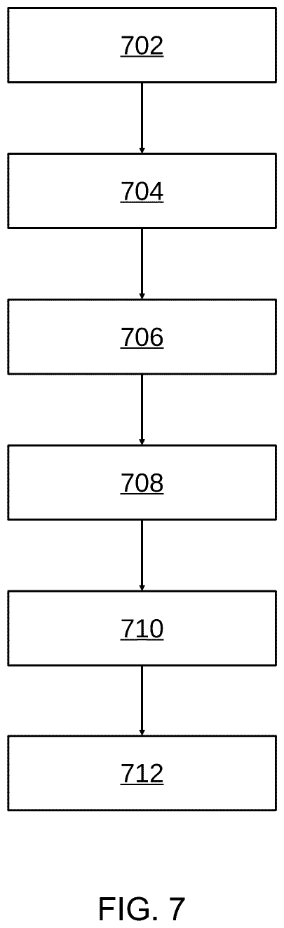

FIG. 7 is a method of installing the in-drawer power management system. The method of manufacturing can include: providing a power outlet charging receptacle dock with a power cord electrically coupled thereto in a block 702; confining a portion of the power cord within a flexible power cord retainer in a block 704; attaching the power outlet charging receptacle dock to a back drawer wall of a drawer of a cabinet in a block 706; mounting a magnetic mounting plate having an alignment mounting location and a final mounting location, and the magnetic mounting plate configured to align the flexible power cord retainer by magnetic force in a block 708; aligning a magnetic mounting bracket to the alignment mounting location and to the final mounting location through magnetic force in a block 710; and electrically coupling the power cord to a wall outlet in a block 712.

Thus, it has been discovered that the in-drawer power management system furnishes important and heretofore unknown and unavailable solutions, capabilities, and functional aspects. The resulting configurations are straightforward, cost-effective, uncomplicated, highly versatile, accurate, sensitive, and effective, and can be implemented by adapting known components for ready, efficient, and economical manufacturing, application, and utilization.

The in-drawer power management system solves the problem of providing a power supply management system that keeps electrical devices powered or charged inside drawers for a cleaner work surface is safely powering and wiring a drawer while providing a quick and easy installation method. Without proper power cord management and correct installation, placing power outlets and USB chargers inside the drawer can pose safety and electrical hazards, and also impede the drawer's proper function. Accordingly, it has been discovered that one or more embodiments of the subject matter of the disclosed invention provides an apparatus, system, and method that provides power charging for electrical devices inside drawers that is easy to install with magnetic mounting components which eliminates the need for precise management, contains a soft and flexible retainer cord system that protects against pinching of power cords and prevents fray and shorts caused by traditional sharp and rigid metal power cord management components.

While the in-drawer power management system has been described in conjunction with a specific best mode, it is to be understood that many alternatives, modifications, and variations will be apparent to those skilled in the art in light of the preceding description. Accordingly, it is intended to embrace all such alternatives, modifications, and variations, which fall within the scope of the included claims. All matters set forth herein or shown in the accompanying drawings are to be interpreted in an illustrative and non-limiting sense.

What is claimed is:

1. An in-drawer power management system comprising:
a power outlet charging receptacle dock;
a power cord electrically coupled to the power outlet charging receptacle dock;
a flexible power cord retainer configured to confine the power cord therethrough;
a magnetic mounting plate having an alignment mounting location and a final mounting location, and the magnetic mounting plate configured to align the flexible power cord retainer by magnetic force; and
a magnetic mounting bracket configured to align to the alignment mounting location or to the final mounting location through magnetic force.

2. The system of claim 1 further comprising: a cover plate affixable to the power outlet charging receptacle dock.

3. The system of claim 1 wherein: the magnetic mounting bracket is affixed to an end of the flexible power cord retainer, and the magnetic mounting bracket is configured to releasably attach to the magnetic mounting plate.

4. The system of claim 1 wherein: the magnetic mounting plate includes a clip, and the magnetic mounting bracket is configured to slide along and to affix to the magnetic mounting plate with the clip.

5. The system of claim 1 wherein: the flexible power cord retainer includes a foldable section and a straight section.

6. An in-drawer power management system comprising:
a power outlet charging receptacle dock configured to attach to a back drawer wall of a drawer of a cabinet;
a power cord electrically coupled to the power outlet charging receptacle dock, the power cord configured to electrically couple to a wall outlet;
a flexible power cord retainer configured to confine the power cord therethrough; and
a magnetic mounting plate having an alignment mounting location and a final mounting location, and the magnetic mounting plate configured to align the flexible power cord retainer by magnetic force; and
a magnetic mounting bracket configured to align to the alignment mounting location or to the final mounting location through magnetic force.

7. The system of claim 6 wherein: the power outlet charging receptacle dock is configured to attach to a front surface of the back drawer wall and extend through the back drawer wall.

8. The system of claim 6 further comprising: a drawer coupling attachment affixed to an end of the flexible power cord retainer for coupling the flexible power cord retainer to a back surface of the back drawer wall.

9. The system of claim 6 wherein: the magnetic mounting bracket is coupled to an end of the flexible power cord retainer, the magnetic mounting plate having a bottom groove configured to direct the power cord therethrough.

10. The system of claim 6 further comprising: a cabinet mounting screw configure to affix the magnetic mounting plate to a back cabinet wall of the cabinet.

11. A method of installing an in-drawer power management system comprising:
providing a power outlet charging receptacle dock with a power cord electrically coupled thereto;
confining a portion of the power cord within a flexible power cord retainer;
mounting a magnetic mounting plate having an alignment mounting location and a final mounting location, and the magnetic mounting plate configured to align the flexible power cord retainer by magnetic force; and
aligning a magnetic mounting bracket to the alignment mounting location and to the final mounting location through magnetic force.

12. The method of claim 11 further comprising: affixing a cover plate to the power outlet charging receptacle dock.

13. The method of claim 11 wherein: confining the power cord within the flexible power cord retainer includes confining the power cord with the flexible power cord retainer having the magnetic mounting bracket affixed to an end of the flexible power cord retainer, the magnetic mounting bracket configured to releasably attach to the magnetic mounting plate.

14. The method of claim 11 wherein: mounting the magnetic mounting plate includes mounting the magnetic mounting plate having a clip, and the magnetic mounting bracket is configured to slide along and to affix to the magnetic mounting plate with the clip.

15. The method of claim 11 wherein: confining the power cord within the flexible power cord retainer includes confining the power cord with the flexible power cord retainer having a foldable section and a straight section.

16. The method of claim 11 further comprising:
attaching the power outlet charging receptacle dock to a back drawer wall of a drawer of a cabinet; and
electrically coupling the power cord to a wall outlet.

17. The system of claim 16 wherein: attaching the power outlet charging receptacle dock includes attaching the power outlet charging receptacle dock to a front surface of the back drawer wall, with the power outlet charging receptacle dock extend through the back drawer wall.

18. The system of claim 16 further comprising: coupling the flexible power cord retainer to a back surface of the back drawer wall with a drawer coupling attachment affixed to an end of the flexible power cord retainer.

19. The system of claim 16 further comprising: directing the power cord through a bottom groove in the magnetic mounting bracket coupled to an end of the flexible power cord retainer.

20. The system of claim 16 further comprising: affixing the magnetic mounting plate to a back cabinet wall of the cabinet with a cabinet mounting screw.
